(19) United States
(12) Patent Application Publication
(10) Pub. No.: US 2015/0294839 A1
(43) Pub. Date: Oct. 15, 2015

(54) PLASMA PROCESSING APPARATUS AND PLASMA PROCESSING METHOD

(71) Applicant: TOKYO ELECTRON LIMITED, Tokyo (JP)

(72) Inventors: Hiroyuki TAKABA, Miyagi (JP); Tetsuya NISHIZUKA, Miyagi (JP); Naoki MATSUMOTO, Miyagi (JP); Michitaka AITA, Miyagi (JP); Takashi MINAKAWA, Miyagi (JP); Kazuki TAKAHASHI, Miyagi (JP); Jun YOSHIKAWA, Miyagi (JP); Motoshi FUKUDOME, Miyagi (JP); Naoki MIHARA, Miyagi (JP); Hiroyuki KONDO, Miyagi (JP)

(73) Assignee: TOKYO ELECTRON LIMITED, Tokyo (JP)

(21) Appl. No.: 14/681,161

(22) Filed: Apr. 8, 2015

(30) Foreign Application Priority Data
Apr. 9, 2014 (JP) 2014-080213

(51) Int. Cl. H01J 37/32

(52) U.S. Cl. CPC H01J 37/3244; H01J 37/3222

(57) ABSTRACT

Disclosed is a plasma processing apparatus including a processing container, a placing table, a central introduction section, and a peripheral introduction section. The central introduction section is provided above the placing table. The central introduction introduces a gas toward the placing table along the axis passing through a center of the placing table. The peripheral introduction section is provided between the central introduction section and a top surface of the placing table in a height direction. In addition, the peripheral introduction section is formed along a side wall. The peripheral introduction section provides a plurality of gas ejection ports arranged in a circumferential direction with respect to the axis. The plurality of gas ejection ports of the peripheral introduction section extend away from the placing table as the gas ejection ports come close to the axis.

### CROSS-REFERENCE TO RELATED APPLICATIONS

This application is based on and claims priority from Japanese Patent Application No. 2014-080213, filed on Apr. 9, 2014, with the Japan Patent Office, the disclosure of which is incorporated herein in its entirety by reference.

### TECHNICAL FIELD

An exemplary embodiment of the present disclosure relates to a plasma processing apparatus and a plasma processing method.

### BACKGROUND

In manufacturing an electronic device, a plasma processing such as, for example, a plasma etching is performed on a processing target object. In the plasma processing, in-plane uniformity is required in processing the processing target object.

Japanese Patent Laid-Open Publication No. 2011-44566 discloses a kind of a plasma processing apparatus proposed for the requirement described above. The plasma processing apparatus disclosed in Japanese Patent Laid-Open Publication No. 2011-44566 is a plasma processing apparatus that generates plasma by microwaves, and includes a placing table, a central introduction section, and a peripheral introduction section. A processing target object is placed on the placing table. The central introduction section introduces a gas from an upper side of the placing table along an axis passing through the center of the placing table in a vertical direction. In addition, the peripheral introduction section introduces a gas from a tube extending in an annular shape at a height between a gas ejection port of the central introduction section and the placing table. The tube of the peripheral introduction section is formed with a plurality of gas ejection ports arranged in the circumferential direction. The plurality of gas ejection ports extends toward the axis to be substantially parallel with the top surface of the placing table. That is, the gas ejection ports of the peripheral introduction section extend toward the axis to be orthogonal to the axis.

### SUMMARY

In one aspect, there is provided a plasma processing apparatus for performing a plasma processing on a processing target object, the plasma processing apparatus. The plasma processing apparatus includes a processing container, a placing table, a central introduction section, and a peripheral introduction section. The processing container includes a side wall extending along an axis to be described later. The placing table is provided within the processing container. The central introduction section is provided above the placing table. The central introduction section is configured to introduce a gas toward the placing table along the axis passing through a center of the placing table. The peripheral introduction section is provided between the central introduction section and a top surface of the placing table in a direction where the axis extends, that is, in the height direction. In addition, the peripheral introduction section is provided along the side wall. That is, the peripheral introduction section is provided to be in contact with the side wall. The peripheral introduction section is configured to provide a plurality of gas ejection ports arranged in a circumferential direction with respect to the axis. The plurality of gas ejection ports of the peripheral introduction section extend away from the placing table as the gas ejection ports come close to the axis. In other words, the plurality of gas ejection ports extend in a direction including a component directed to the center of a space within the processing container and a component directed away from the placing table along the axis. That is, the plurality of gas ejection ports extend obliquely upwardly.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a cross-sectional view schematically illustrating a plasma processing apparatus according to an exemplary embodiment.

FIG. 2 is a plan view illustrating an exemplary slot plate.

FIG. 3 is a plan view illustrating an exemplary dielectric window.

FIG. 4 is a cross-sectional view taken along line IV-IV in FIG. 3.

FIG. 5 is a plan view illustrating a state where the slot plate illustrated in FIG. 2 is provided on the dielectric window illustrated in FIG. 3.

FIG. 6 is a view illustrating a part of a peripheral introduction section in an enlarged scale.

FIG. 7 is a flowchart illustrating a plasma processing method according to an exemplary embodiment.

FIGS. 8A to 8F are graphs representing simulation results.

FIGS. 9A and 9B are views illustrating a structure and a wafer fabricated in test examples and comparative test example.

FIG. 10 is a graph representing test results.

### DETAILED DESCRIPTION

In the following detailed description, reference is made to the accompanying drawings, which form a part hereof. The illustrative embodiments described in the detailed description, drawing, and claims are not meant to be limiting. Other exemplary embodiments may be utilized, and other changes may be made without departing from the spirit or scope of the subject matter presented here.

In the plasma processing apparatus disclosed in Japanese Patent Laid-Open Publication No. 2011-44566, after the gas is ejected from the peripheral introduction section toward the axis, the streams of the gas are separated into gas streams directed to the upper side, and gas streams directed toward the lower side, i.e. toward the placing table. Accordingly, the gas streams introduced from the peripheral introduction section and directed toward the processing target object and the gas introduced from the central introduction section may collide with each other on the processing target object. Accordingly, a gas stay region may be generated on the processing target object. When such a region is generated, the non-uniform processing is caused on the processing target object.

Accordingly, it becomes necessary to suppress a gas from staying on the processing target object in the plasma processing apparatus.

In a first aspect, there is provided a plasma processing apparatus for performing a plasma processing on a processing target object. The plasma processing apparatus includes a processing container, a placing table, a central introduction section, and a peripheral introduction section. The processing container includes a side wall extending along an axis to be described later. The placing table is provided within the processing container. The central introduction section is provided above the placing table. The central introduction section is configured to introduce a gas toward the placing table along the axis passing through a center of the placing table. The peripheral introduction section is provided between the central introduction section and a top surface of the placing table in a direction where the axis extends, that is, in the height direction. In addition, the peripheral introduction section is provided along the side wall. That is, the peripheral introduction section is provided to be in contact with the side wall. The peripheral introduction section is configured to provide a plurality of gas ejection ports arranged in a circumferential direction with respect to the axis. The plurality of gas ejection ports of the peripheral introduction section extend away from the placing table as the gas ejection ports come close to the axis. In other words, the plurality of gas ejection ports extend in a direction including a component directed to the center of a space within the processing container and a component directed away from the placing table along the axis. That is, the plurality of gas ejection ports extend obliquely upwardly.

According to the plasma processing apparatus, the gas introduced from the peripheral introduction section flows obliquely upwardly to join the gas introduced from the central introduction section, or to flow with the gas flow introduced from the central introduction section. Accordingly, on the processing target object placed on the placing table, the gases are caused to flow from the center of the processing target object to the edge of the processing target object. Thus, the staying of the gases on the processing target object is be suppressed.

In an exemplary embodiment, the plurality of gas ejection ports of the peripheral introduction section may extend to have an angle in a range of 15 degrees to 60 degrees with respect to a plane perpendicular to the axis.

In an exemplary embodiment, the plasma processing apparatus may further include an antenna configured to introduce microwaves into the processing container. The antenna includes a dielectric window which is provided above the placing table to face the placing table and is in contact with a space within the processing container. A gas ejection port of the central introduction section is formed in the dielectric window to extend along the axis. In an exemplary embodiment, the antenna may be a radial line slot antenna.

In a second aspect, there is provided a plasma processing method using any one of the plasma processing apparatus of any one of the first aspect and various exemplary embodiment described above. The plasma processing method includes: introducing a gas from the central introduction section and the peripheral introduction section so as to process a processing target object placed on the placing table by plasma of the gas. According to the plasma processing method, in-plane uniformity in processing the processing target object may be improved.

In an exemplary embodiment, the processing target object may include a film formed of silicon, germanium, or silicon germanium, and the gas may include a gas which is corrosive to the film. An example of the gas may be HBr gas.

As described above, a plasma processing apparatus capable of suppressing stay of a gas on a processing target object and a plasma processing method using the plasma processing apparatus are provided.

Hereinafter, various exemplary embodiments will be described in detail with reference to the accompanying drawings. Meanwhile, the same or corresponding components in respective drawings will be denoted by the same symbols.

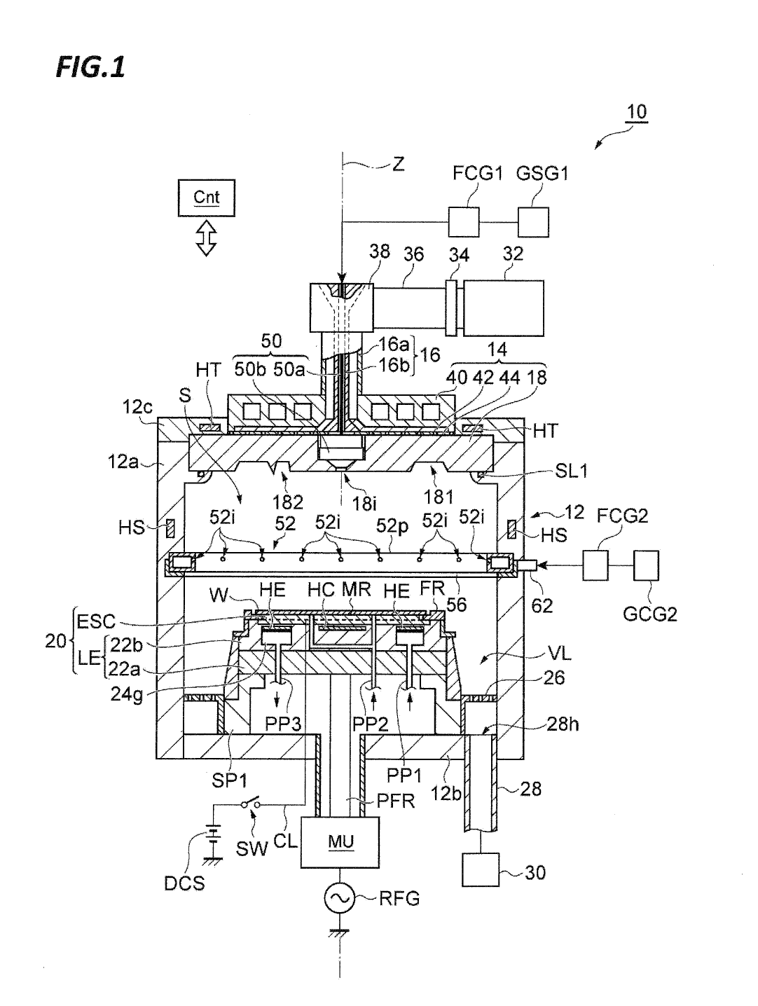

First, a plasma processing apparatus according to an exemplary embodiment will be described. FIG. 1 is a cross-sectional view schematically illustrating a plasma processing apparatus according to an exemplary embodiment. The plasma processing apparatus 10 illustrated in FIG. 1 is provided with a processing container 12. The processing container 12 provides a processing space S to accommodate a processing target object. Meanwhile, in the following description, the processing target object may be referred to as a wafer W.

The processing container 12 includes a side wall 12a. In addition, the processing container 12 may further include a bottom 12b and a ceiling 12c. The side wall 12a has a substantially cylindrical shape extending in a direction where an axis Z extends. The axis Z is an axis passing through, for example, the center of a placing table to be described later in the vertical direction. In an exemplary embodiment, the central axis of the side wall 12a coincides with the axis Z. The inner diameter of the side wall 12a is, for example, 540 mm.

The bottom 12b is formed at the lower end side of the side wall 12a. In addition, the upper end of the side wall 12a is opened. The opening of the upper end of the side wall 12a is closed by a dielectric window 18. The dielectric window 18 is sandwiched between the upper end of the side wall 12a and the ceiling 12c. A sealing member SL1 may be interposed between the dielectric window 18 and the upper end of the side wall 12a. The sealing member SL1 is, for example, an O-ring, and contributes to the hermetic sealing of the processing container 12.

The plasma processing apparatus 10 further includes a placing table 20 provided in the processing container 12. The placing table 20 is provided below the dielectric window 18. For example, the distance between the bottom surface of the dielectric window 18 and the top surface of the placing table 20 is 245 mm. In an exemplary embodiment, the placing table 20 includes a lower electrode LE and an electrostatic chuck ESC.

The lower electrode LE includes a first plate 22a and a second plate 22b. Both the first plate 22a and the second plate 22b have substantially a disc shape, and are made of, for example, aluminum. The first plate 22a is supported by a cylindrical support SP1. The support SP1 extends vertically upwardly from the bottom 12b. The second plate 22b is provided on the first plate 22a and is conductive with the first plate 22a.

The lower electrode LE is electrically connected with a high frequency power supply RFG via a power feeding rod PFR and a matching unit MU. The high frequency power supply RFG supplies a high frequency bias power to the lower electrode LE. The high frequency bias power generated by the high frequency power supply RFG may have a predetermined frequency suitable for controlling the energy of ions drawn into the wafer W, for example, a frequency of 13.65 MHz. The matching unit MU accommodates a matcher configured to match an impedance of the high frequency power supply RFG side and an impedance of the load side such as, for example, mainly an electrode, plasma, and the processing container 12 with each other. For example, a blocking capacitor for self-bias generation may be included within the matcher.

The electrostatic chuck ESC is installed on the second plate 22b. The electrostatic chuck ESC provides a mounting region MR in the processing space S to place a wafer W thereon. The mounting region MR is a substantially circular region substantially orthogonal to the axis Z, and may have a diameter which is substantially the same as or slightly smaller than that of the wafer W. In addition, the mounting region MR forms the top surface of the placing table 20 and the center of the mounting region MR, i.e., the center of the placing table 20 is positioned on the axis Z.

The electrostatic chuck ESC holds the wafer W by an electrostatic attractive force. The electrostatic chuck ESC includes an attraction electrode provided within a dielectric material. The attraction electrode of the electrostatic chuck ESC is connected with a direct current (“DC”) power supply DSC via a switch SW and a coated wire CL. The electrostatic chuck ESC may attract the wafer to the top surface thereof by a Coulomb force generated by the DC voltage applied from the DC power supply DCS so as to hold the wafer W. A focus ring FR is provided radially outside of the electrostatic chuck ESC to surround the periphery of the wafer W in an annular form.

An annular flow path 24g is formed within the second plate 22b. The flow path 24g is supplied with a coolant from a chiller unit through a pipe PP1. The coolant supplied to the flow path 24g is recovered to the chiller unit through a pipe PP3. In addition, in the plasma processing apparatus 10, a heat transfer gas such as, for example, He gas, is supplied from a heat transfer gas supply unit to a space between the top surface of the electrostatic chuck ESC and the rear surface of the wafer W through a supply pipe PP2.

A space is provided in the outside of the outer periphery of the placing table 20, i.e., between the placing table 20 and the side wall 12a. The space is formed as an exhaust path VL having an annular shape in a plan view. In the middle of the exhaust path VL in the axis Z direction, an annular baffle plate 26 is provided in which a plurality of through holes is formed. The exhaust path VL is connected with an exhaust pipe 28 that provides an exhaust port 28h. The exhaust pipe 28 is attached to the bottom 12b of the processing container 12. An exhaust apparatus 30 is connected to the exhaust pipe 28. The exhaust apparatus 30 includes a pressure regulator and a vacuum pump such as, for example, a turbo molecular pump. With the exhaust apparatus 30, the processing space S within the processing container 12 may be decompressed to a desired vacuum degree. In addition, when the exhaust apparatus 30 is operated, the gas supplied to the wafer W flows along the surface of the wafer W toward the outside of the edge of the wafer W and is exhausted through the exhaust path VL from the outer periphery of the placing table 20.

In an exemplary embodiment, the plasma processing apparatus 10 may further include heaters HT, HS, HC, and HE as a temperature control mechanism. The heater HT is installed within the ceiling 12c and extends annularly to surround an antenna 14. In addition, the heater HS is installed within the side wall 12a to extend annularly. The heater HC is installed within the second plate 22b or within the electrostatic chuck ESC. The heater HC is installed below the central portion of the mounting region MR described above, i.e., in a region intersecting the axis Z. In addition, the heater HE extends annularly to surround the heater HC. The heater HE is installed below the outer peripheral edge of the mounting region MR described above.

In an exemplary embodiment, the plasma processing apparatus 10 may further include an antenna 14, a coaxial waveguide 16, a microwave generator 32, a tuner 34, a waveguide 36, and a mode converter 38. The antenna 14, the coaxial waveguide 16, the dielectric window 18, the microwave generator 32, the tuner 34, the waveguide 36, and the mode converter 38 form a plasma generation source for exciting a gas introduced into the processing container.

The microwave generator 32 generates microwaves having a frequency of 2.45 GHz, for example. The microwave generator 32 is connected to an upper portion of the coaxial waveguide 16 via the tuner 34, the waveguide 36, and the mode converter 38. The coaxial waveguide 16 extends along the axis Z which is the central axis thereof.

The coaxial waveguide 16 includes an outer conductor 16a and an inner conductor 16b. The outer conductor 16a has a cylindrical shape extending around the axis Z. The lower end of the outer conductor 16a is electrically connected to an upper portion of the cooling jacket 40 having a conductive surface. The inner conductor 16b is installed inside and coaxially to the outer conductor 16a. The inner conductor 16b has a cylindrical shape extending around the axis Z. The lower end of the inner conductor 16b is connected to a slot plate 44 of the antenna 14.

In an exemplary embodiment, the antenna 14 is a radial line slot antenna. The antenna 14 is disposed within the opening formed in the ceiling 12c to face the placing table 20. The antenna 14 includes a dielectric plate 42, a slot plate 44, and a dielectric window 18. The dielectric plate 42 serves to shorten the wavelengths of microwaves and has substantially a disc shape. The dielectric plate 42 is made of, for example, quartz or alumina. The dielectric plate 42 is sandwiched between the slot plate 44 and the bottom surface of the cooling jacket 40.

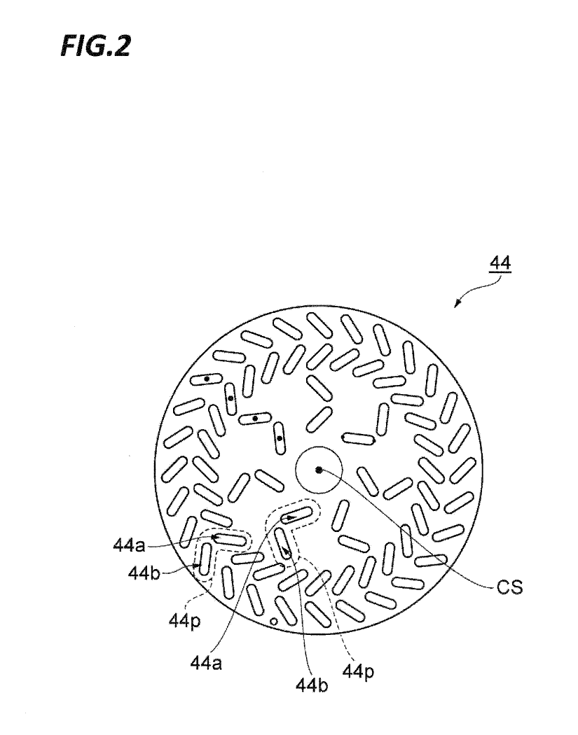

FIG. 2 is a plan view illustrating an exemplary slot plate. The slot plate 44 is thin and disc-shaped. Each of the opposite surfaces of the slot plate 44 in the thickness direction is flat. The center CS of the slot plate 44 is positioned on the axis Z. The slot plate 44 is provided with a plurality of slot pairs 44p. Each of the plurality of slot pairs 44p includes two slot holes 44a and 44b that penetrate the plate in the thickness direction. The planar shape of each of the slot holes 44a and 44b is an elongated hole shape. In each slot pair 44p, a direction where the major axis of the slot hole 44a extends and a direction where the major axis of the slot hole 44b extends intersect with each other or are orthogonal to each other. The plurality of slot pairs 44p are arranged in a circumferential direction. In the example illustrated in FIG. 2, the plurality of slot pairs 44p are arranged in the circumferential direction along two coaxial circles. On each of the coaxial circles, the slot pairs 44p are arranged substantially at regular intervals. The slot plate 44 is installed on a top surface 18u of the dielectric window 18.

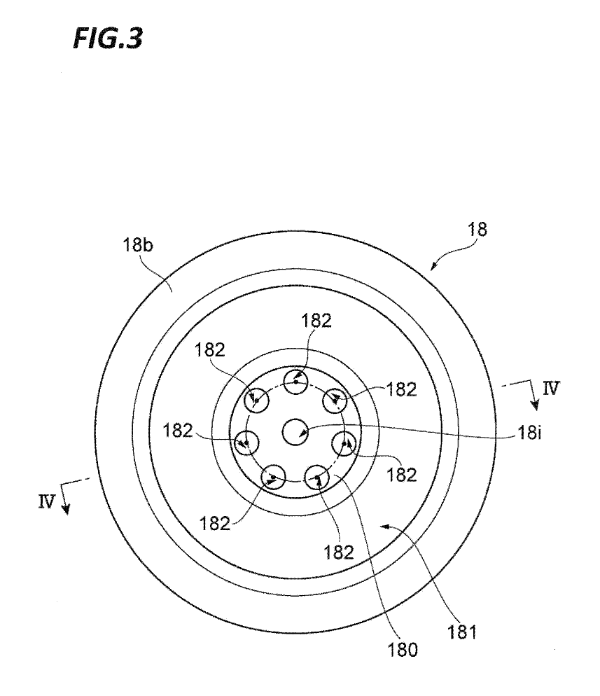

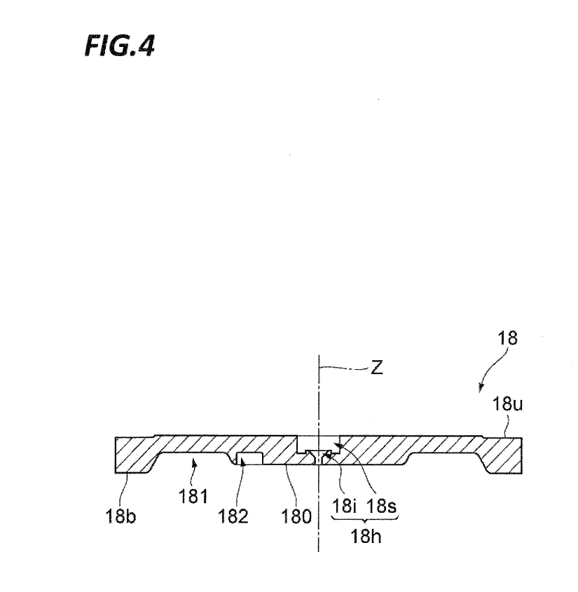

FIG. 3 is a plan view illustrating an exemplary dielectric window, and FIG. 4 is a cross-sectional view taken along line IV-IV in FIG. 3. As illustrated in FIGS. 3 and 4, the dielectric window 18 is substantially a disc-shaped member which is made of a dielectric material such as, for example, quartz. A through hole 18h is formed at the center of the dielectric window 18. The upper portion of the through hole 18h is a space 18s in which an injector 50b of a central introduction section 50 is accommodated and the lower portion is a gas ejection port 18i of the central introduction section 50. The injector 50b and the gas ejection port 18i will be described below. Meanwhile, the central axis of the dielectric window 18 coincides with the axis Z.

The surface of the dielectric window opposite to the top surface 18u, i.e., a bottom surface 18b is a surface which is in contact with the processing space S and is positioned at the plasma generation side. The bottom surface 18b defines various shapes. Specifically, the bottom surface 18b has a flat face 180 in the central region surrounding the gas ejection port 18i. The flat face 180 is a flat face orthogonal to the axis Z. The bottom surface 18b defines an annular first recess 181. The first recess 181 is annularly continuous to the flat face 180 in the radial outside region of the flat face 180 and is recessed toward the inner portion of the dielectric window 18 in the plate thickness direction in a taper shape.

In addition, the bottom surface 18b defines a plurality of second recesses 182. The plurality of second recesses 182 are recessed toward the inner portion in the plate thickness direction from the flat face 180. The number of the plurality of second recesses 182 is seven in the example illustrated in FIGS. 3 and 4. The plurality of second recesses 182 are formed at regular intervals along the circumferential direction. In addition, each of the plurality of second recesses 182 has a circular planar shape on the plane orthogonal to the axis Z.

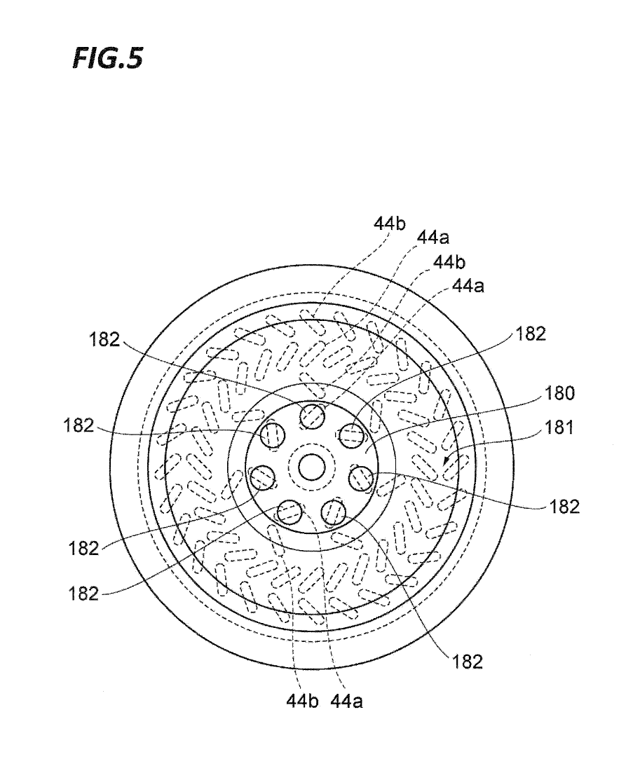

FIG. 5 is a plan view illustrating a state where the slot plate illustrated in FIG. 2 is installed on the dielectric window illustrated in FIG. 3, in which the dielectric window 18 is viewed from the lower side. As illustrated in FIG. 5, when viewed on a plane, i.e., when viewed in the axis Z direction, the slot pairs 44p provided along the radially outer coaxial circle overlap with the first recess 181. In addition, the slot holes 44b of the slot pairs 44p formed along the radially inner coaxial circle overlap with the first recess 181. Furthermore, the slot holes 44a of the slot pairs 44p formed along the radially inner coaxial circle overlap with the plurality of second recesses 182.

Reference will be made again to FIG. 1. In the plasma processing apparatus 10, the microwaves generated by the microwave generator 32 are propagated to the dielectric plate 42 through the coaxial waveguide 16 to be fed to the dielectric window 18 from the slot holes 44a and 44b of the slot plate 44. Just below the dielectric window 18, the energy of the microwaves is concentrated to the first recess 181 and the second recesses 182 which are defined by portions having a relatively thine plate thickness. Accordingly, in the plasma processing apparatus 10, the plasma may be generated to be stably distributed in the circumferential direction and radial direction.

In addition, the plasma processing apparatus 10 is provided with a central introduction section 50 and a peripheral introduction section 52. The central introduction section 50 includes a duct 50a, an injector 50b, and a gas ejection port 18i. The duct 50a is configured to pass through the inner bore of the inner conductor 16b of the coaxial waveguide 16. An end of the duct 50a extends to the inside of the space 18s (see, e.g., FIG. 4) defined in the dielectric window 18 along the axis Z. The injector 50b is accommodated in the inside of the space 18s and below the end of the duct 50a. The injector 50b is formed with a plurality of through holes extending in the axis Z direction. In addition, the dielectric window 18 provides the gas ejection port 18i described above. The gas ejection port 18i is continuous to the lower side of the space 18s and also extends along the axis Z. The central introduction section 50 with this configuration supplies a gas to the injector 50b through the duct 50a, and ejects the gas from the injector 50b through the gas ejection port 18i. In this way, the central introduction section 50 ejects the gas to a location just below the dielectric window 18 along the axis Z. That is, the central introduction section 50 introduces the gas into a plasma generation region having a high electron temperature. In addition, the gas ejected from the central introduction section 50 flows substantially along the axis toward the central region of the wafer W.

The central introduction section 50 is connected with a first gas source group GSG1 via a first flow rate control unit group FCG1. The first gas source group GSG1 includes a plurality of first gas sources. The plurality of first gas sources are sources of various gases required for processing a wafer W. When etching a polycrystal silicon layer, the gases may include a corrosive gas such as, for example, HBr gas. In addition, the gases may include various gases such as a rare gas such as Ar or He and oxygen gas. The first flow rate control unit group FCG1 includes a plurality of flow rate controllers and a plurality of opening/closing valves. Each first gas source is connected to the central introduction section 50 via a flow rate controller and an opening/closing valve which correspond to the first flow rate control unit group FCG1.

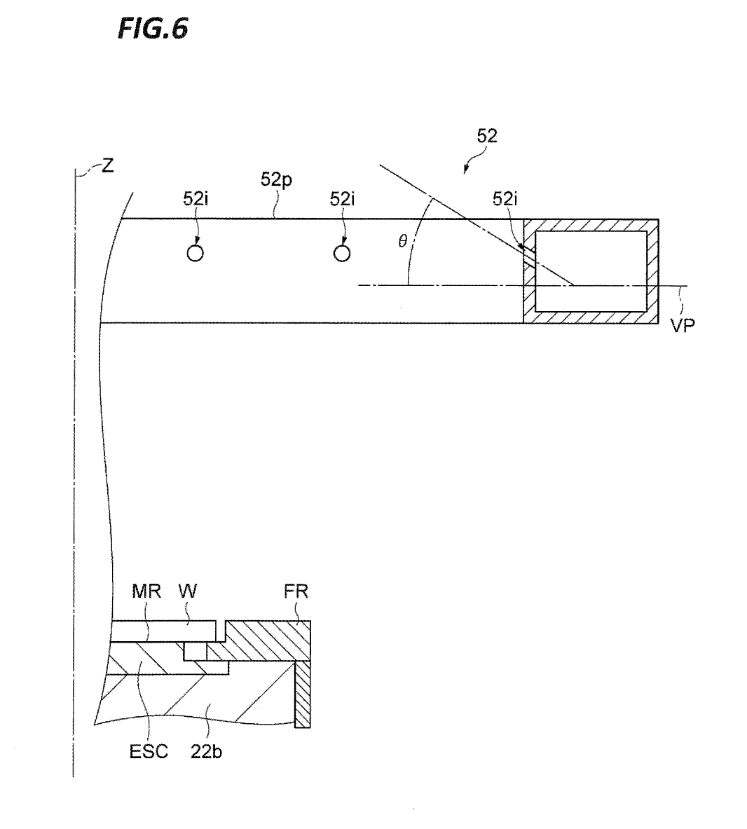

FIG. 6 is a view illustrating a part of the peripheral introduction section in an enlarged scale. As illustrated in FIGS. 1 and 6, the peripheral introduction section 52 is installed between the gas ejection port 18i of the central introduction section 50 and the top surface of the placing table 20 in the height direction, i.e. in the axis Z direction. The peripheral introduction section 52 introduces the gas into the inside of the processing space S from positions arranged along the side wall 12a. The peripheral introduction section 52 includes a plurality of gas ejection ports 52i. The plurality of gas ejection ports 52i are arranged along the circumferential direction below the gas ejection port 18i and above the placing table 20.

In an exemplary embodiment, the peripheral introduction section 52 includes an annular tube 52p. The tube 52p is disposed at a distance of, for example, 90 mm above from the top surface of the placing table 20. The tube 52p is formed with a plurality of gas ejection ports 52i. The annular tube 52p may be made of, for example, quartz. As illustrated in FIG. 1, the annular tube 52p is in contact with the side wall 12a, in an exemplary embodiment. In addition, as illustrated in FIG. 6, the plurality of gas ejection ports 52i extend away from the top surface of the placing table 20 as the gas ejection ports 52i come close to the axis Z. In other words, the plurality of gas ejection ports 52i extend in a direction having a component directed toward the center of the processing space S and a component spaced away from the placing table 20 along the axis Z, i.e. obliquely upwardly. Assuming a virtual plane VP orthogonal to the axis Z, the center line of each gas ejection port 52i forms an angle θ with respect to the virtual plane VP. The angle θ may be in a range of 15 degrees to 60 degrees.

The annular tube 52p of the peripheral introduction section 52 is connected with a second gas source group GSG2 via a gas supply block 62 and a second flow rate control unit group FCG2. The second gas source group GSG2 includes a plurality of second gas sources. The plurality of second gas sources are sources of various gases required for processing a wafer W. When etching a polycrystal silicon layer, the gases may include a corrosive gas such as, for example, HBr gas. The gases may include various gases such as a rare gas such as Ar or He, and oxygen gas. The second flow rate control unit group FCG2 includes a plurality of flow rate controllers and a plurality of opening/closing valves. Each of the second gas sources is connected to the peripheral introduction section 52 via a flow rate controller and an opening/closing valve corresponding to the second flow rate control unit group FCG2.

In the plasma processing apparatus 10, the types of gases introduced into the processing space S from the central introduction section 50, and the flow rates of one or more gases introduced into the processing space S from the central introduction section 50 may be independently controlled. In addition, the types of gases introduced into the processing space S from the peripheral introduction section 52 and the flow rates of one or more gases introduced into the processing space S from the peripheral introduction section 52 may be independently controlled.

In addition, the gas introduced from the peripheral introduction section 52 flows obliquely upwardly within the processing space S to join the gas introduced from the central introduction section 50 or to flow with a gas stream introduced from the central introduction section 50. Accordingly, on the wafer W placed on the placing table 20, the gas flows in a direction directed from the center of the wafer W to the edge of the wafer W. Thus, the stay of the gas on the wafer W is suppressed. As a result, in-plane uniformity in the processing of the wafer W is improved.

In an exemplary embodiment, the plasma processing apparatus 10 may further include a control unit Cnt, as illustrated in FIG. 1. The control unit Cnt may be a controller such as, for example, a programmable computer device. The control unit Cnt may control each component of the plasma processing apparatus 10 according to a program based on a recipe. For example, the control unit Cnt may transmit a control signal to the flow rate controllers and the opening/closing valves of the first flow rate control unit group FCG1 so as to control the types of gases introduced from the central introduction section 50 and the flow rates of the gases. In addition, the control unit Cnt may transmit a control signal to the flow rate controllers and the opening/closing valves of the second flow rate control unit group (FCG2) so as to control the types of gases introduced from the peripheral introduction section 52 and the flow rates of the gases. In addition, the control unit Cnt may supply a control signal to the microwave generator 32, the high frequency power supply RFG, and the exhaust apparatus 30 so as to control the power of microwaves, the power and ON/OFF of a high frequency bias power, and a pressure within the processing container 12. Further, the control unit Cnt may transmit a control signal to a heater power supply connected to the heaters HT, HS, HC, and HE so as to adjust the temperatures of the heaters HT, HS, HC, and HE.

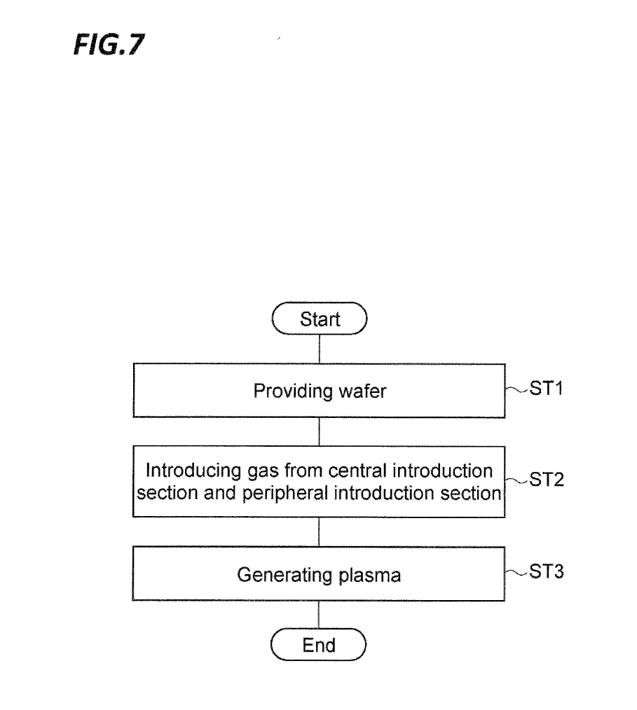

Hereinafter, descriptions will be made on a plasma processing method performed using the plasma processing apparatus 10 described above. FIG. 7 is a flowchart illustrating a plasma processing method according to an exemplary embodiment. As illustrated in FIG. 7, in the present method, first, a wafer W is provided in step ST1. Specifically, the wafer W is placed on the placing table 20 and attracted by the electrostatic chuck ESC. Then, the exhaust apparatus 30 is operated so that the pressure of the space within the processing container 12 is set to a predetermined pressure. Subsequently, in step ST2, gases are introduced into the processing container 12 from the central introduction section 50 and the peripheral introduction section 52. Subsequently, in step ST3, plasma of the gases introduced into the processing container 12 is generated. The wafer W is processed by the plasma of the gases.

In an exemplary embodiment, a processing target film of the wafer W is a film formed of silicon, germanium, or silicon germanium. When the wafer W of the exemplary embodiment is processed, the gases include a gas having corrosiveness with respect to the film. For example, when a polycrystal silicon film is the processing target film, the gases include HBr gas. In addition, the gases may further include a rare gas and/or oxygen gas.

According to the plasma processing method using the plasma processing apparatus 10 described above, the gases do not stay on the wafer W and thus, in-plane uniformity in the film processing of the wafer W is improved.

Hereinafter, descriptions will be made on simulations performed for evaluation of the plasma processing apparatus 10. In the simulations, gas flowing speeds in the radial direction with respect to the axis Z were calculated at 5 mm above from the top surface of the placing table 20. In addition, in the simulations, the following conditions were simulated. Meanwhile, when the angle θ of the gas ejection ports 52i has a plus value, it indicates that the gas ejection ports 52i extend obliquely upwardly, and when the angle θ of the gas ejection ports 52i has a minus value, it indicates that the gas ejection ports 52i extend obliquely downwardly.

### Simulation Conditions

Diameter of side wall 12a of processing container 12: 540 mm

Distance of peripheral introduction section 52 from top surface of placing table 20: 90 mm

Distance between top surface of placing table 20 and flat face 180 of dielectric window 18: 245 mm

Processing gas
Ar gas: 1000 sccm
HBr gas: 800 sccm

Gas flow rate of central introduction section 50: gas flow rate of peripheral introduction section 52=70:30

Pressure within processing container 12: 100 mTorr (13.33 Pa)

Angle (θ) of gas ejection ports 52i: six types (60 degrees, 45 degrees, 30 degrees, 15 degrees, 0 degrees, and −45 degrees)

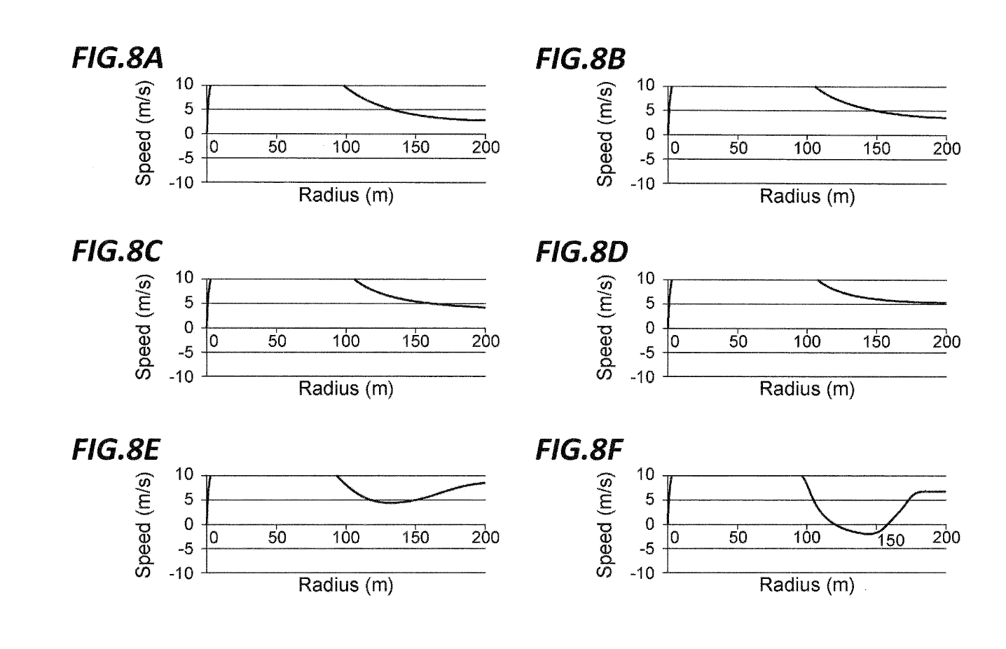

FIGS. 8A to 8F are graphs representing simulation results. FIGS. 8A, 8B, 8C, 8D, 8E, and 8F are graphs representing simulation results when the angle θ of the gas ejection ports 52i is 60 degrees, 45 degrees, 30 degrees, 15 degrees, 0 degree, and −45 degrees, respectively. In each of the graphs of FIGS. 8A to 8F, the horizontal axis represents a distance from the axis Z in a radial direction, and the vertical axis represents a gas flowing speed in the radial direction with respect to the axis Z.

As illustrated in FIG. 8F, when the angle θ of the gas ejection ports 52i is −45 degrees, that is, when the gas ejection ports 52i extend obliquely downwardly, a region where the speed has a minus value occurs. This shows that a gas stay region occurs on the wafer W. In addition, as illustrated in FIG. 8E, even when the angle θ of the gas ejection ports 52i is 0 degrees, a region where the speed has a minimum value occurs on the way in the radial direction. This also shows that a gas stay region occurs on the wafer W. Meanwhile, as illustrated in FIGS. 8A, 8B, 8C, and 8D, when the angle θ of the gas ejection ports 52i is 60 degrees, 45 degrees, 30 degrees, and 15 degrees, the speed smoothly decreases as the distance from the axis Z increases in the radial direction. From this, it has been found that when the gas ejection ports 52i extend obliquely upwardly, the gas is suppressed from staying on the wafer W.

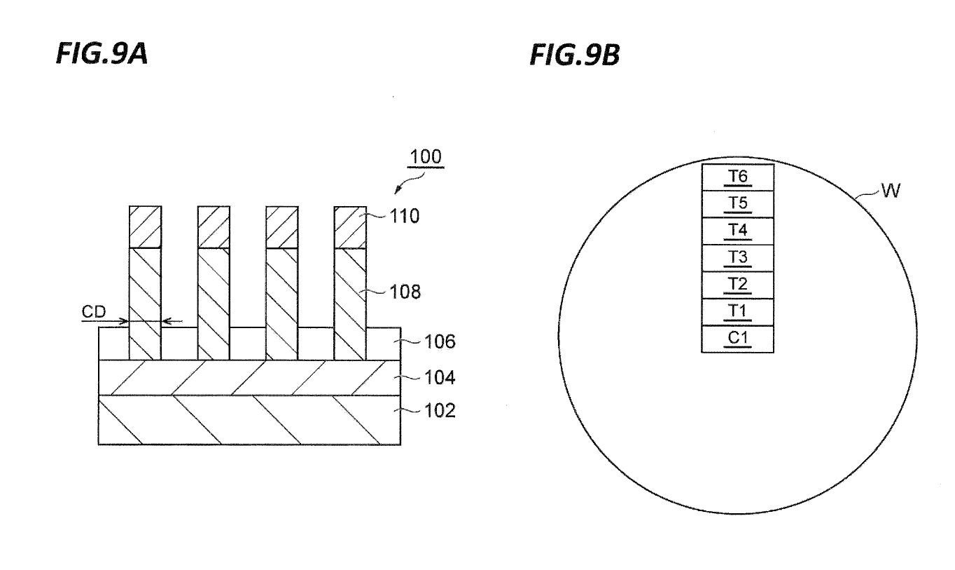

Subsequently, descriptions will be made on Test Example 1 and Comparative Test Examples 1 and 2 which were performed using the plasma processing apparatus 10. In Test Example 1, a wafer W having a structure 100 illustrated in FIG. 9A was fabricated using the plasma processing apparatus 10. Specifically, the structure 100 includes a substrate 102, a silicon oxide film 104, fins 106, multiple regions 108 made of polycrystal silicon, and a mask 110 made of a silicon nitride film. The silicon oxide film 104 is formed on the substrate 102. The fins 106 include polycrystal silicon and have a substantially rectangular parallelepiped shape. The multiple regions 108 are formed in a way as to lie astride the fins 106 on the silicon oxide film 104. The multiple regions 108 have a substantially rectangular parallelepiped shape and extend parallel to each other. In addition, the mask 110 is provided on the multiple regions 108. In Test Example 1, in order to fabricate the structure 100, a polycrystal silicon layer was formed to cover the silicon oxide film 104 and the fins 106, the mask 110 was formed on the polycrystal silicon layer, and the polycrystal silicon layer was etched using the plasma processing apparatus 10 so as to form the regions 108.

Conditions of Test Example 1 were as follows.

### Conditions of Test Example 1

Diameter of side wall 12a of processing container 12: 540 mm

Distance of peripheral introduction section 52 from top surface of placing table 20: 90 mm

Distance between top surface of placing table 20 and flat face 180 of dielectric window 18: 245 mm

Processing gases
Ar gas: 1000 sccm
HBr gas: 800 sccm
Cl₂ gas: 35 sccm
O₂ gas: 18 sccm

Gas flow rate of central introduction section 50: gas flow rate of peripheral introduction section 52=70:30

Pressure within processing container 12: 120 mTorr (16 Pa)

Angle (θ) of gas ejection ports 52i: 45 degrees

Microwaves: 2.45 GHz, 1500 W

High frequency bias power: 13.56 MHz, 300 W

In Comparative Test Examples 1 and 2, structures 100 were fabricated in the same method as Test Example 1. However, in Comparative Test Example 1, the angle θ of the gas ejection ports 52i was set to −45 degrees, and in Comparative Test Example 2, the angle θ of the gas ejection ports 52i was set to 0 degrees.

In addition, the widths CD of the regions 108 on the boundaries between the fins 106 and the regions 108 of the structures 100 fabricated in Test Example 1 and Comparative Test Examples 1 and 2 were measured in each of seven sections C1, T1, T2, T3, T4, T5, and T6 which were equally divided from a region from the center to the edge of each wafer W, as illustrated in FIG. 9B.

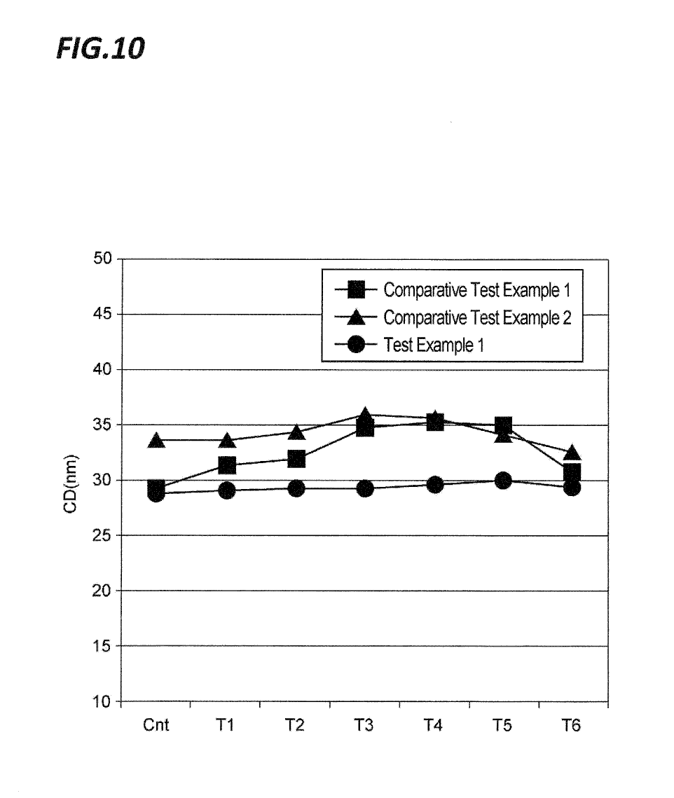

FIG. 10 represents the test results. In particular, FIG. 10 is a graph representing the widths CD of the structures 100 fabricated in Test Example 1 and Comparative Test Examples 1 and 2. In the graph illustrated in FIG. 10, the horizontal axis represents the seven sections described above, and the vertical axis represents CD. As illustrated in FIG. 10, in Comparative Test Example 1 and Comparative Test Example 2, CDs in the sections T3, T4, and T5 became larger than CDs in the other sections. From this result, it is estimated that in Comparative Test Example 1 and Comparative Test Example 2, the gas stayed above the sections T3, T4, and T5. Meanwhile, in Test Example 1, the values of CDs in all the sections became approximately equal to each other. From this result, it has been found that the stay of gas on the wafer may be suppressed by ejecting the gas obliquely upwardly from the peripheral introduction section 52, and as a result, the in-plane uniformity in processing the wafer W may be improved.

Although various exemplary embodiments have been described above, various modified embodiments may be made without being limited to the exemplary embodiments described above. For example, the plasma processing apparatus 10 excites a gas using microwaves as a plasma source. However, the plasma processing apparatus may have any plasma source. For example, the plasma processing apparatus may be either a capacitively coupled plasma processing apparatus or an inductively coupled plasma processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus for performing a plasma processing on a processing target object, the plasma processing apparatus comprising:
a processing container including a side wall;
a placing table provided within the processing container;
a central introduction section formed above the placing table, the central introduction section being configured to introduce a gas toward the placing table along an axis passing through a center of the placing table; and
a peripheral introduction section formed between the central introduction section and a top surface of the placing table in a direction where the axis extends, and along the side wall, the peripheral introduction section being configured to provide a plurality of gas ejection ports arranged in a circumferential direction with respect to the axis,
wherein the plurality of gas ejection ports extend away from the placing table as the plurality of gas ejection ports come close to the axis.

2. The plasma processing apparatus of claim 1, wherein the plurality of gas ejection ports extend to have an angle in a range of 15 degrees to 60 degrees with respect to a plane perpendicular to the axis.

3. The plasma processing apparatus of claim 1, further comprising:
an antenna configured to introduce microwaves into the processing container,
wherein the antenna includes a dielectric window which is provided above the placing table to face the placing table and is in contact with a space within the processing container, and
a gas ejection port of the central introduction section is formed in the dielectric window to extend along the axis.

4. The plasma processing apparatus of claim 3, wherein the antenna is a radial line slot antenna.

5. A plasma processing method using the plasma processing apparatus defined in claim 1, the plasma processing method comprising:
introducing a gas from the central introduction section and the peripheral introduction section so as to process a processing target object placed on the placing table by plasma of the gas.

6. The plasma processing method of claim 5, wherein the processing target object includes a film formed of silicon, germanium, or silicon germanium, and
the gas includes a gas which is corrosive to the film.

7. The plasma processing method of claim 5, wherein the gas includes HBr gas.
